(19) United States
(12) Patent Application Publication
(10) Pub. No.: US 2026/0157215 A1
(43) Pub. Date: Jun. 4, 2026

(54) ANISOTROPIC CONDUCTIVE BONDING MATERIAL AND BONDED STRUCTURE USING THE SAME

(71) Applicant: Electronics and Telecommunications Research Institute, Daejeon (KR)

(72) Inventors: Yong Sung EOM, Daejeon (KR); Jin Hyuk OH, Daejeon (KR); Ki Seok JANG, Daejeon (KR); Ji Ho JOO, Daejeon (KR); Gwang Mun CHOI, Daejeon (KR); Kwang Seong CHOI, Daejeon (KR); Seok Hwan MOON, Daejeon (KR); Jung Ho SHIN, Daejeon (KR); Chan Mi LEE, Daejeon (KR); Sol Yee LIM, Daejeon (KR)

(21) Appl. No.: 19/405,229

(22) Filed: Dec. 1, 2025

(30) Foreign Application Priority Data
Nov. 29, 2024 (KR) 10-2024-0175306
May 9, 2025 (KR) 10-2025-0060598

(51) Int. Cl. H10W 72/30; C09J 9/02; C09J 11/04; C09J 11/06; C09J 163/00; H01B 1/22

(52) U.S. Cl. CPC H10W 72/325; C09J 9/02; C09J 11/04; C09J 11/06; C09J 163/00; H10W 72/01361; H10W 72/07335; H10W 72/07338; H10W 72/352; C09J 2203/326; C09J 2301/416; C09J 2400/16; C09J 2463/00; H01B 1/22

(57) ABSTRACT

The present invention provides an anisotropic conductive bonding material including a curable matrix, conductive particles, and polymer spacers, wherein the conductive particles include gallium (Ga) or a gallium-based alloy, and the gallium-based alloy includes gallium and one or more metals selected from indium (In), dysprosium (Dy), tin (Sn), and zinc (Zn).

### CROSS-REFERENCE TO RELATED APPLICATION

This application claims priority to and the benefit of Korean Patent Application No. 10-2024-0175306, filed on Nov. 29, 2024, and Korean Patent Application No. 10-2025-0060598, filed on May 9, 2025 the disclosures of which are incorporated herein by reference in their entirety.

### BACKGROUND

### 1. Field of the Invention

The present invention relates to an anisotropic conductive bonding material and a bonding method using the same. More particularly, the present invention relates to an anisotropic conductive bonding material and a bonded structure including a conductive bonding layer.

### 2. Description of the Related Art

In general, anisotropic conductive bonding materials perform fine-pitch bonding in electronic devices and are cured and become electrically conductive when heat is applied, and thus are widely used for bonding display panels such as liquid crystal displays (LCDs) and organic light-emitting diode (OLED) displays.

An anisotropic conductive bonding material is composed of a thermosetting polymer resin and conductive particles and is manufactured in the form of a paste or a film.

FIG. 1 is a schematic view of a conventional anisotropic conductive bonding material including polymer balls each coated with a conductive metal, and FIG. 2 is a schematic view illustrating a case in which metal pads of upper and lower substrates are electrically bonded.

Referring to FIGS. 1 and 2, an anisotropic conductive bonding material 10 is disposed between metal pads 2 of a substrate 1 and a device 5 that will be bonded, and when high pressure and heat are applied, conductive polymer balls 4 having elasticity come into physical contact with the metal pads 2 positioned above and below in the anisotropic conductive bonding material 10 while maintaining elliptical shapes. At this time, a thermosetting polymer resin 3 surrounding the conductive polymer balls 4 undergoes an instantaneous curing reaction. As a result, the conductive polymer balls 4, which have been deformed into elliptical shapes, exhibit electrical conductivity merely through physical contact between metal layers on their surfaces. However, there is a limit to achieving high conductivity. In this case, because high temperature and high pressure must be used for the thermosetting bonding process of the anisotropic conductive bonding material, not only may the substrate or the device be damaged by heat, but electrical conductivity is also formed merely by simple physical contact of the metal coated on the surfaces of the conductive polymer balls 4 having elasticity. As a result, the metal contact area is significantly reduced, which increases the likelihood of heat generation when a high current is applied.

Further, when an external impact is applied to the bonded module, cracks are easily generated in the bonding material, and as a result, the physical contact of the conductive polymer balls 4 is reduced even by a small external impact, which not only causes heat generation but also increases the possibility of a short circuit.

Accordingly, there is a need to develop an anisotropic conductive bonding material that can prevent thermal damage to the substrate or the device and that is not easily short-circuited even under external impact during substrate bonding.

### SUMMARY OF THE INVENTION

The present invention is directed to providing an anisotropic conductive bonding material capable of preventing thermal damage to a substrate and an electronic device without requiring high temperature and high pressure and of not being prone to crack formation in a bonded region even when an external impact is applied to a module bonded using the anisotropic conductive bonding material, thereby suppressing heat generation caused by a reduction in physical contact area and significantly reducing the risk of a short circuit.

The present invention is also directed to providing a bonded structure using an anisotropic conductive bonding material, which is capable of preventing oxidation of liquid gallium metal powder, which is easily oxidized, and of significantly improving electrical conductivity at a bonded region by enhancing the wettability of liquid gallium metal.

The above and other objectives of the present invention can all be achieved by the present invention described in detail below.

One aspect of the present invention relates to an anisotropic conductive bonding material.

The anisotropic conductive bonding material includes a curable matrix, conductive particles, and polymer spacers, wherein the conductive particles include gallium (Ga) or a gallium-based alloy, wherein the gallium-based alloy includes gallium and one or more metals selected from indium (In), dysprosium (Dy), tin (Sn), and zinc (Zn).

The conductive particles may have an average diameter of 1 μm to 100 μm.

The curable matrix may include a thermosetting resin, a curing agent, a reducing agent, and a catalyst.

The reducing agent may be any one or more selected from formic acid, acetic acid, lactic acid, glutamic acid, oleic acid, rosolic acid, 2,2-bis(hydroxymethylene) propanoic acid, butanoic acid, propanoic acid, tannic acid, gluconic acid, pentanoic acid, hexanoic acid, hydrobromic acid, hydrochloric acid, uric acid, hydrofluoric acid, sulfuric acid, benzylglutaric acid, malic acid, phosphoric acid, oxalic acid, uranic acid, hydrochloride, perchloric acid, gallic acid, phosphorous acid, citric acid, malonic acid, tartaric acid, phthalic acid, cinnamic acid, glutaric acid, propionic acid, stearic acid, ascorbic acid, acetylsalicylic acid, azelaic acid, benzylic acid, and fumaric acid.

The anisotropic conductive bonding material may include 10 to 30 parts by weight of the conductive particles and 1 to 5 parts by weight of the polymer spacers based on 100 parts by weight of the curable matrix.

Another aspect of the present invention relates to a bonded structure including the anisotropic conductive bonding material.

The bonded structure includes a first electronic component, a second electronic component facing the first electronic component, and a conductive bonding layer interposed between the first electronic component and the second electronic component and electrically connecting the first electronic component and the second electronic component, wherein the conductive bonding layer includes the anisotropic conductive bonding material.

The first electronic component or the second electronic component includes a printed circuit board.

The polymer spacers included in the conductive bonding layer may maintain a spacing between the first electronic component and the second electronic component.

The first electronic component may include a substrate and a first metal pad formed on an upper portion of the substrate and in contact with the conductive bonding layer, and the second electronic component may include an electronic device and a second metal pad formed on a lower portion of the electronic device and in contact with the conductive bonding layer.

Still another aspect of the present invention relates to a method of manufacturing a bonded structure using the anisotropic conductive bonding material.

The method of manufacturing a bonded structure includes forming a laminate by applying the anisotropic conductive bonding material of claim 1 to a first electronic component and stacking a second electronic component on the anisotropic conductive bonding material, forming a bonded structure by applying a pressure to the laminate and irradiating the laminate with a laser, and curing the bonded structure.

The anisotropic conductive bonding material may be prepared by pulverizing a conductive particle agglomeration and mixing the pulverized conductive particles with the curable matrix and the polymer spacers.

The pressure may be greater than or equal to 0.4 MPa, and the laser may have an output power greater than or equal to 100 W.

The laser may increase a temperature of the bonded structure at a rate of 200° C./sec or less.

Oxide films may be present on surfaces of the pulverized conductive particles, and the oxide films may be removed by the pressure and the laser.

The pulverized conductive particles may be prepared by preparing a mixture by introducing the conductive particle agglomeration into a solvent, pulverizing the conductive particle agglomeration by applying ultrasonic waves to the mixture, and drying the mixture to remove the solvent.

Yet another aspect of the present invention relates to a method of manufacturing a bonded structure by controlling an applied pressure.

The method of manufacturing a bonded structure includes forming a laminate by applying the anisotropic conductive bonding material to a first electronic component and stacking a second electronic component on the anisotropic conductive bonding material, forming a bonded structure by applying a pressure to the laminate, and curing the bonded structure.

The anisotropic conductive bonding material may be prepared by introducing a conductive particle agglomeration into a thermosetting resin to prepare a mixed composition, pulverizing the conductive particle agglomeration in the mixed composition by applying ultrasonic waves, and mixing a curable matrix and polymer spacers into the mixed composition.

Oxide films may not be present on surfaces of the pulverized conductive particles.

The mixed composition may further include a curing agent and a reducing agent.

The pressure may be greater than or equal to 0.4 MPa.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a schematic view of a conventional anisotropic conductive bonding material including polymer balls each coated with a conductive metal;

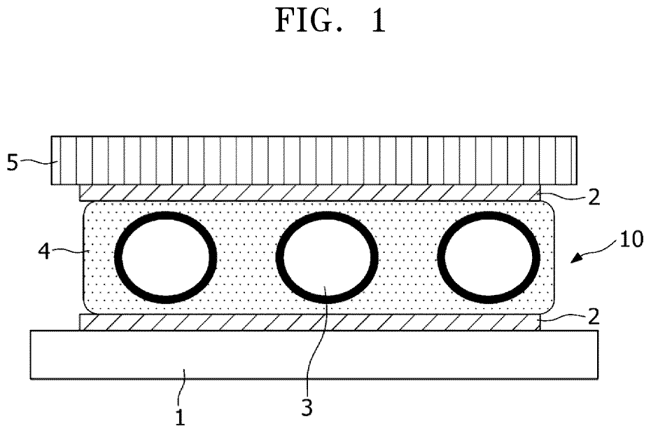

FIG. 2 is a schematic view illustrating a case in which metal pads of upper and lower substrates are electrically bonded;

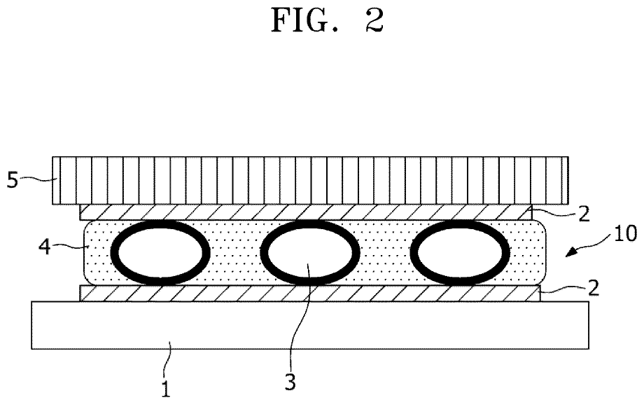

FIG. 3 is a schematic view illustrating a bonded structure according to one embodiment of the present invention;

FIG. 4 is a process flowchart of a method of manufacturing a bonded structure using an anisotropic conductive bonding material according to another aspect of the present invention;

FIG. 5 is a schematic view illustrating a case in which a laser is radiated onto and pressure is applied to the bonded structure in the method of manufacturing a bonded structure using the anisotropic conductive bonding material according to one embodiment of the present invention;

FIG. 6 is a schematic view illustrating a state in which a base resin is cured after the pressure applied to the bonded structure is released in the method of manufacturing a bonded structure using the anisotropic conductive bonding material according to one embodiment of the present invention;

FIG. 7 is a process flowchart of a method of manufacturing a bonded structure using the anisotropic conductive bonding material according to still another aspect of the present invention;

FIG. 8 is a schematic view illustrating a bonded structure in which an anisotropic conductive bonding material including conductive particles containing a gallium-based alloy is disposed between a substrate and an electronic device in the method of manufacturing a bonded structure using the anisotropic conductive bonding material according to another embodiment of the present invention;

FIG. 9 is a schematic view illustrating a pressing process applied to the bonded structure including conductive particles containing a gallium-based alloy in the method of manufacturing a bonded structure using the anisotropic conductive bonding material according to another embodiment of the present invention;

FIG. 10 is a schematic view illustrating a state in which a curable matrix is cured after the pressing process of the bonded structure including conductive particles containing a gallium-based alloy in the method of manufacturing a bonded structure using the anisotropic conductive bonding material according to another embodiment of the present invention;

FIG. 11 is a schematic view illustrating an example of the substrate and the electronic device in the method of manufacturing a bonded structure using the anisotropic conductive bonding material according to one embodiment of the present invention;

FIG. 12 illustrates a state in which an anisotropic conductive bonding material is applied onto a polyimide (PI) substrate and covered with a silicon device in the method of manufacturing a bonded structure using the anisotropic conductive bonding material according to one embodiment of the present invention;

FIG. 13 illustrates the result of a differential scanning calorimetry (DSC) analysis and a scanning electron microscope (SEM) image of the conductive particles including gallium in the anisotropic conductive bonding material according to one embodiment of the present invention;

FIG. 14 is a schematic view illustrating a bonded structure in which an anisotropic conductive bonding material including conductive particles whose surface oxide films have not been removed is disposed;

FIG. 15 is a schematic view illustrating a state in which the surface oxide films of the conductive particles are removed when a low-power area laser is radiated onto and a low pressure is applied to the bonded structure in which the anisotropic conductive bonding material including conductive particles whose surface oxide films have not been removed is disposed;

FIG. 16 is a schematic view illustrating the bonded structure in a state in which a conductive path is formed as the surface oxide films of some conductive particles are removed; and

FIG. 17 is a graph showing results of measuring 4-point probe resistance between the bonded substrate and electronic device while varying the output power of an area laser according to the method of manufacturing a bonded structure using the anisotropic conductive bonding material according to one embodiment of the present invention.

### DETAILED DESCRIPTION OF EXEMPLARY EMBODIMENTS

Hereinafter, the present invention will be described in more detail with reference to the accompanying drawings. However, the drawings are provided merely to facilitate understanding of the present invention, and the present invention is not limited thereto. In addition, the figures, dimensions, ratios, angles, numbers, and the like disclosed in the drawings are merely illustrative and are not limited to matters shown in the present invention.

Throughout the specification, like reference numerals refer to like components. Further, in describing the present invention, detailed descriptions of well-known technologies will be omitted when it is determined that they may unnecessarily obscure the gist of the present invention.

Terms such as “including,” “having,” and “composed of” used herein are intended to allow other components to be added unless the terms are used with the term “only.” Any references to the singular may include the plural unless expressly stated otherwise.

Components are interpreted to include an ordinary error range even if not expressly stated.

In the present specification, the numerical range “a to b” is defined as “≥a and ≤b.”

In the present specification, all numerical ranges include a 95% confidence interval.

One aspect of the present invention relates to an anisotropic conductive bonding material.

The anisotropic conductive bonding material includes a curable matrix 100, conductive particles 200, and polymer spacers 300.

The curable matrix 100 may include a thermosetting resin, a curing agent, a reducing agent, and a catalyst.

The curable matrix 100 may be cured to form a bonded region between a first electronic component 1 and a second electronic component 5, in which an anisotropic conductive bonding material is disposed, and may enhance the wettability of the conductive particles 200 by removing oxide films 210 of the conductive particles 200 to electrically connect the substrate 1 and the electronic device 5.

The thermosetting resin may include one or more of epoxy, phenoxy, bismaleimide, unsaturated polyester, urethane, urea, phenol-formaldehyde, vulcanized rubber, melamine resin, polyimide, epoxy novolac resin, and cyanate ester.

The above-described types of thermosetting resins may support the conductive particles 200 to be dispersed and may have reducing properties to remove the oxide films on the surfaces of the conductive particles 200.

The curing agent may be any one or more selected from aliphatic amines, aromatic amines, cycloaliphatic amines, phenalkamines, imidazoles, carboxylic acids, anhydrides, polyamide-based hardeners, phenolic curing agents, and waterborne curing agents.

The above-described types of curing agents may be mixed with the thermosetting resin and may allow the thermosetting resin to be cured in response to thermal shock caused by laser irradiation and compression.

The above-described types of curing agents may change a polymer structure of the thermosetting resin to form a polymer matrix and may form crosslinking bonds to improve strength and heat resistance.

The reducing agent may be any one or more selected from formic acid, acetic acid, lactic acid, glutamic acid, oleic acid, rosolic acid, 2,2-bis(hydroxymethylene) propanoic acid, butanoic acid, propanoic acid, tannic acid, gluconic acid, pentanoic acid, hexanoic acid, hydrobromic acid, hydrochloric acid, uric acid, hydrofluoric acid, sulfuric acid, benzylglutaric acid, malic acid, phosphoric acid, oxalic acid, uranic acid, hydrochloride, perchloric acid, gallic acid, phosphorous acid, citric acid, malonic acid, tartaric acid, phthalic acid, cinnamic acid, glutaric acid, propionic acid, stearic acid, ascorbic acid, acetylsalicylic acid, azelaic acid, benzylic acid, and fumaric acid.

The above-described types of reducing agents may allow the curable matrix 100 to have reducing properties. In particular, carboxyl-based reducing agents are preferable because they can more effectively remove an oxide film formed on a metal surface by chemically bonding with oxygen on the metal surface.

The reducing agent may implement the effects of the present invention by reducing the conductive particles 200 and removing the oxide films 210 formed on the surfaces thereof. Specifically, when the conductive particles 200 include a metal such as liquid gallium and are formed into fine particles at room temperature, strong oxide films 210 are formed on the surfaces of the particles, making it difficult to exhibit electrical conductivity. However, the above-described types of reducing agents may allow the curable matrix 100 to exhibit reducing properties, thereby removing the oxide films 210 on the surfaces of the conductive particles 200, improving the wettability of the gallium metal, and enabling the conductive particles to exhibit electrical conductivity.

The catalyst may include 1-methyl imidazole, 2-methyl imidazole, dimethylbenzyl imidazole, 1-decyl-2-methylimidazole, benzyl dimethyl amine, trimethyl amine, diethylaminopropylamine, pyridine, 1,8-diazobicyclo [5,4,0]undec-7-ene, 2-heptadecylimidazole, boron trifluoride monoethylamine, and 1-(3-(2-hydroxyphenyl) prop-2-enyl) imidazole.

The above-described types of catalysts may control a reaction rate within the polymer matrix of the thermosetting resin and, for example, may accelerate a curing reaction when a laser is radiated.

The curable matrix 100 includes a thermosetting resin, a curing agent, a reducing agent, and a catalyst, and may be easily applied between the first electronic component 1 and the second electronic component 5 to form a bonded structure 2000. The curable matrix 100 may remove the oxide films 210 on the conductive particles 200 to impart wettability to the conductive particles, thereby inducing an electrical connection between metal pads.

The conductive particles 200 are gallium-based alloys including gallium (Ga) or one or more metals selected from gallium (Ga) or indium (In), dysprosium (Dy), tin (Sn), and zinc (Zn).

For example, the conductive particles 200 may be gallium or a eutectic gallium-indium alloy (Eutectic Gallium Indium; EGaIn), of which a particle size is controlled, and may be Ga—In alloys having various mixing ratios, Ga—In—Dy alloys, Ga—In—Sn alloys, or Ga—In—Zn alloys.

A melting point of the gallium is 37° C., a melting point of the eutectic gallium-indium alloy is 19° C., and melting points of the gallium-based alloys are 16° C. or lower. Because high temperature and high pressure are not required to induce the wettability of the conductive particles 200, bonding by laser irradiation is possible during the manufacturing of the bonded structure 2000, thereby preventing thermal damage to the substrate 1 and the electronic device 5.

When gallium or gallium-based alloys are produced as the conductive particles 200 at room temperature, very strong oxide films 210 may be formed. However, the curable matrix 100 may exhibit reducing properties, and when an anisotropic conductive bonding material 1000 is irradiated with a laser while adjusting a laser output power and pressed under an adjusted pressure, the oxide films 210 on the surfaces of the conductive particles 200 may be effectively removed, thereby allowing the conductive particles 200 to exhibit excellent wettability.

The conductive particles 200 including the gallium or gallium-based alloys are dispersed in the curable matrix 100 and may exhibit electrical conductivity and very low resistance even in both solid and liquid states. Since the conductive particles 200 maintain a liquid state at room temperature or higher and are capable of freely changing shape, the conductive particles 200 exhibit very low stress, thereby preventing cracks from occurring under external impact.

The conductive particles 200 may be included in an amount of 10 to 30 parts by weight based on 100 parts by weight of the curable matrix.

When the conductive particles 200 are included within the above range, the anisotropic conductive bonding material can realize the target electrical conductivity.

The conductive particles 200 may have an average diameter of 1 μm to 100 μm.

Within the above range, the conductive particles 200 may be melted by heating and instantaneous temperature elevation caused by laser irradiation, and the oxide films 210 formed on the surfaces of the conductive particles 200 may also be easily removed. When the average particle diameter exceeds the above range, the risk of a short circuit between electrodes may increase.

The polymer spacers 300 may determine a thickness of the anisotropic conductive bonding material 1000. For example, when the anisotropic conductive bonding material 1000 is disposed between the first electronic component 1 and the second electronic component 5 to form the bonded structure 2000, the polymer spacers 300 may adjust a spacing between the first electronic component 1 and the second electronic component 5 according to the sizes of the polymer spacers 300.

The polymer spacers 300 may include one or more selected from poly(methyl methacrylate) (PMMA), polystyrene (PS), polycarbonate (PC), silica, and alumina, and the polymer spacers 300 of such types may withstand the pressure during the pressing process and may adjust the thickness of the anisotropic conductive bonding material 1000 by elastic force when the pressure is released.

The polymer spacers 300 may have an average diameter of 1 μm to 100 μm, and the thickness of the conductive bonding layer in the bonded structure 2000 including the anisotropic conductive bonding material 1000 may be determined by selecting the polymer spacers 300 within the above range.

The polymer spacers 300 may be included in an amount of 1 to 5 parts by weight based on 100 parts by weight of the curable matrix.

With the polymer spacers 300 included within the above range, the thickness of the anisotropic conductive bonding material 1000 after curing may be controlled, the formation of conductive paths in the plane of the anisotropic conductive bonding material 1000 may be prevented, and the conductive paths may be formed in a vertical direction. In addition, by adjusting the spacing between the polymer spacers 300, a short circuit between adjacent metal pads can be effectively prevented. When the content of the conductive particles 200 deviates from the above ratio, a short circuit may be caused between the metal pads to be bonded, and when the content of the polymer spacers 300 deviates from the above ratio, not only is there a high possibility that an electrical connection between the upper and lower metal pads will be hindered, but excessive bonding pressure may also be required, resulting in potential damage to the bonded region.

Accordingly, the anisotropic conductive bonding material according to one aspect of the present invention may be readily applied between the substrate 1 and the electronic device 5 to form the bonded structure 2000, and during the formation of the bonded structure 2000, the oxide films 210 on surfaces of the conductive particles 200 included in the anisotropic conductive bonding material may be effectively removed by adjusting the output power of the laser and the pressure applied, thereby enhancing wettability and improving electrical conductivity. In addition, because the bonded structure 2000 may be formed at room temperature by laser irradiation, a high-temperature and high-pressure curing process is not required, and thus thermal damage to the substrate 1 and the electronic device 5 may be effectively prevented.

Another aspect of the present invention relates to the bonded structure 2000 including the anisotropic conductive bonding material.

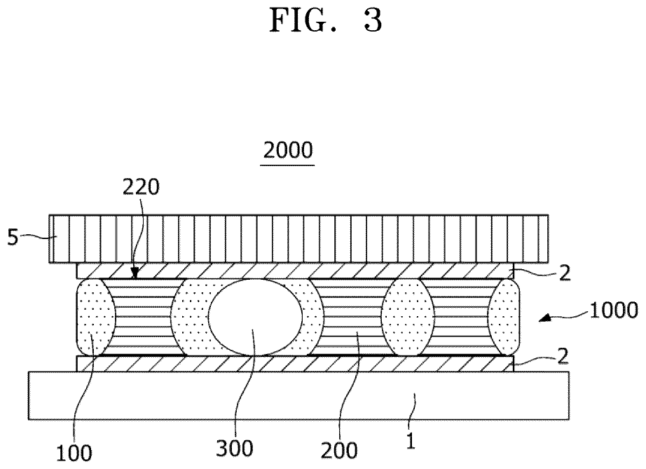

FIG. 3 is a schematic view illustrating the bonded structure 2000 according to one embodiment of the present invention.

Referring to FIG. 3, the bonded structure 2000 includes a first electronic component 1, a conductive bonding layer 1000, and a second electronic component 5.

The first electronic component 1 may be a printed circuit board (PCB) and may include a flexible PCB (FPCB).

In one embodiment, the second electronic component 5 may include a printed circuit board.

The first electronic component 1 may include a substrate and a first metal pad 2, and the first metal pad 2 may be provided above the substrate. The metal pad may include a conductive material. For example, the metal pad may include one or more selected from gold (Au), silver (Ag), copper (Cu), aluminum (Al), nickel (Ni), and tungsten (W).

The first metal pad 2 may be disposed on the first electronic component 1 to form an electrical circuit. Specifically, the first metal pad 2 may be formed of metal lines having adjustable lengths and widths, with a pitch between the metal lines being adjustable.

Warpage may occur in the first electronic component 1. Specifically, when warpage occurs in the substrate of the first electronic component 1, electrical conductivity may be lost, but when the conductive bonding layer 1000 is provided, electrical conductivity may be maintained even when warpage occurs in the substrate.

The conductive bonding layer 1000 is interposed between the first electronic component 1 and the second electronic component 5 and may electrically connect the first electronic component 1 and the second electronic component 5.

The conductive bonding layer 1000 may be disposed on the substrate of the first electronic component 1 and is formed by applying the anisotropic conductive bonding material onto the substrate and curing the anisotropic conductive bonding material after laser irradiation and pressing.

Specifically, after applying the anisotropic conductive bonding material onto the substrate, laser irradiation may be performed while pressing, or the oxide films 210 on the surfaces of the conductive particles 200 included in the anisotropic conductive bonding material may be removed by pressing alone, thereby enhancing wettability and enabling an electrical connection with the first metal pad 2.

The conductive bonding layer 1000 includes polymer spacers 300, and the polymer spacers 300 may maintain a constant spacing between the first electronic component 1 and the second electronic component 5. When the first metal pad 2 is formed of metal lines, the polymer spacers 300 may prevent a short circuit between adjacent metal pads 2 and induce the formation of conductive paths in a vertical direction of the conductive bonding layer 1000.

The conductive bonding layer 1000 may include a liquid-phase region at room temperature.

Since the conductive bonding layer 1000 is formed by applying and curing the anisotropic conductive bonding material and the conductive particles 200 include gallium or a gallium-based alloy that may include a liquid-phase region at room temperature, stress may be greatly reduced, and the occurrence of cracks in the conductive bonding layer may be significantly reduced even when a strong external force is applied. When cracks do not occur in the conductive bonding layer 1000, a short circuit does not occur within the conductive bonding layer, and heat concentration in a partial region of the conductive bonding layer is prevented, thereby effectively preventing thermal damage to the substrate or the electronic device.

The second electronic component 5 is provided to face the first electronic component 1 and is specifically disposed above the conductive bonding layer 1000.

The second electronic component 5 may be an electronic device and, for example, may be a semiconductor chip, a sensor device, a photovoltaic device, an optical device, or the like.

A second metal pad 2 may be provided below the second electronic component 5.

The second metal pad 2 may be the same component as the above-described first metal pad 2, and may be electrically connected to the conductive bonding layer.

Accordingly, the bonded structure 2000 according to the present invention includes the conductive bonding layer 1000 formed by applying the anisotropic conductive bonding material between the first electronic component 1 and the second electronic component 5. As a result, the bonded structure 2000 may not only improve a bonding strength between the first electronic component 1 and the second electronic component 5 and provide high electrical conductivity between the first electronic component 1 and the second electronic component 5 by enhancing the wettability of the conductive particles 200 of the anisotropic conductive bonding material, but also effectively prevent the occurrence of cracks caused by external forces, a short circuit resulting therefrom, and thermal damage to the substrate and the electronic device due to heat concentration.

Still another aspect of the present invention relates to a method of manufacturing a bonded structure using the anisotropic conductive bonding material.

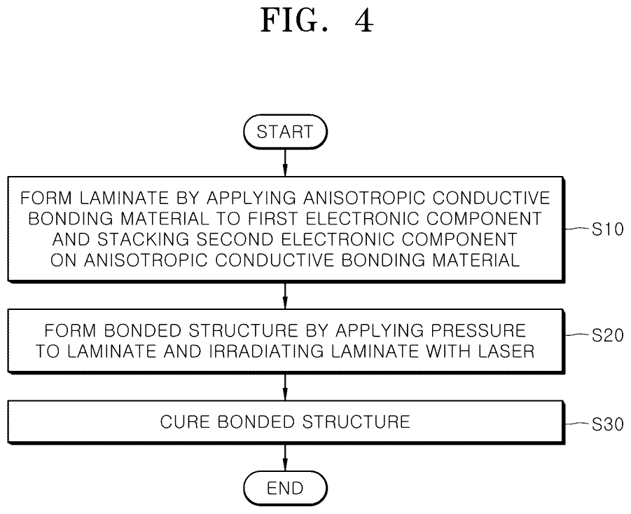

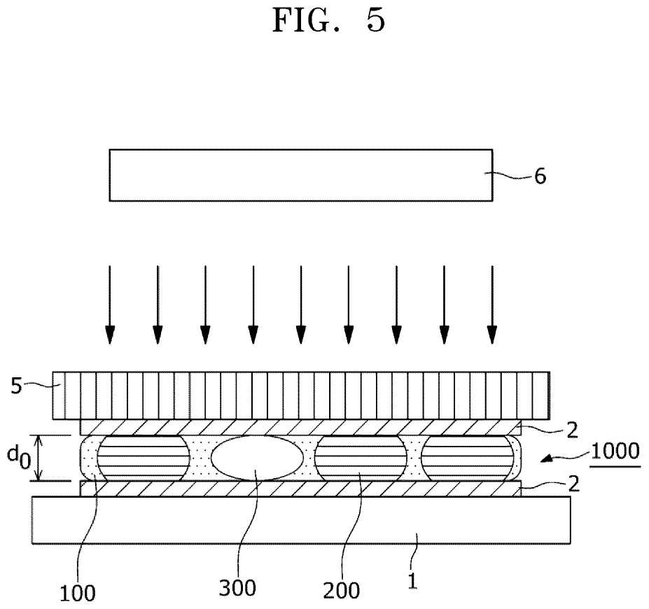

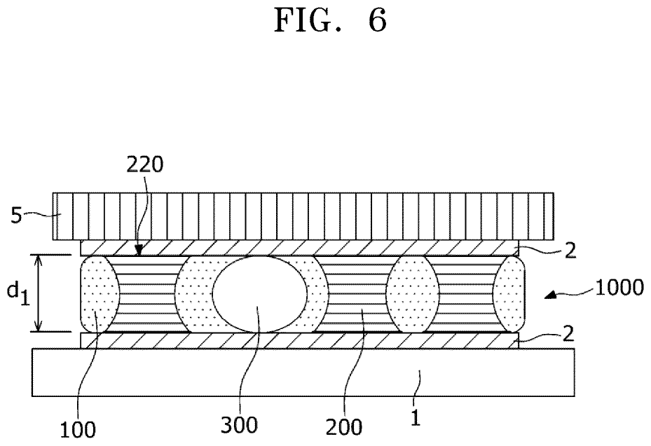

FIG. 4 is a process flowchart of the method of manufacturing a bonded structure using the anisotropic conductive bonding material according to still another aspect of the present invention, FIG. 5 is a schematic view illustrating a case in which a laser is radiated onto and pressure is applied to the bonded structure in the method of manufacturing a bonded structure using the anisotropic conductive bonding material according to one embodiment of the present invention, and FIG. 6 is a schematic view illustrating a state in which a base resin is cured after the pressure applied to the bonded structure is released in the method of manufacturing a bonded structure using the anisotropic conductive bonding material according to one embodiment of the present invention.

Referring to FIGS. 4 to 6, the method of manufacturing a bonded structure using the anisotropic conductive bonding material includes forming a laminate by applying an anisotropic conductive bonding material to a first electronic component 1 and stacking a second electronic component 5 on the anisotropic conductive bonding material, forming a bonded structure 2000 by applying a pressure to the laminate and irradiating the laminate with a laser, and curing the bonded structure 2000.

First, the anisotropic conductive bonding material may be prepared by pulverizing a conductive particle agglomeration and mixing the pulverized conductive particles with a curable matrix and polymer spacers.

For example, conductive particles 200 may be prepared by ultrasonically treating a conductive particle agglomeration including gallium, and the gallium may be mixed in a low-viscosity solvent such as acetone or an alcohol-based solvent and then ultrasonically treated to prepare the conductive particles 200 having an average diameter of 1 μm to 100 μm.

It is preferable to prepare the conductive particles 200 by ultrasonic treatment, but the present invention is not particularly limited thereto, as long as the conductive particles 200 can be prepared within the above range.

When the conductive particles 200 are formed of gallium or a gallium-based alloy, strong oxide films 210 may be formed on surfaces of the conductive particles 200, and when the oxide films 210 are formed on the surfaces of the conductive particles 200, the bonded structure 2000 cannot exhibit a desired electrical conductivity.

The conductive particles 200 are mixed with a curable matrix 100 and polymer spacers 300 to prepare the anisotropic conductive bonding material.

In one embodiment, the anisotropic conductive bonding material may include 10 to 30 parts by weight of the conductive particles and 1 to 5 parts by weight of the polymer spacers, based on 100 parts by weight of the curable matrix.

Since the curable matrix 100, the conductive particles 200, and the polymer spacers 300 have the same configurations as those described above for the above-described anisotropic conductive bonding material, repeated descriptions thereof will be omitted.

The anisotropic conductive bonding material having the above composition may form a conductive bonding layer 1000 to provide electrical communication and may exhibit a very strong bonding strength between a substrate and an electronic device.

The anisotropic conductive bonding material is applied to the first electronic component 1, and the second electronic component 5 is stacked on the anisotropic conductive bonding material to prepare a laminate (S10).

The anisotropic conductive bonding material may be in a solution state, and in this case, the laminate may be prepared by applying the anisotropic conductive bonding material to the first electronic component 1 and covering the anisotropic conductive bonding material with the second electronic component 5.

The bonded structure 2000 is formed by applying a pressure to the laminate and irradiating the laminate with a laser (S20)

Referring to FIG. 5, pressure application and laser irradiation are simultaneously performed on the bonded structure 2000 so that the curable matrix 100 of the conductive bonding layer 1000 exhibits reducing properties, thereby removing the oxide films 210 on the surfaces of the conductive particles 200 and enhancing the wettability of the conductive particles 200.

Although the conductive particles pulverized by ultrasonic treatment have oxide films on their surfaces, the oxide films may be effectively removed by the pressure application and the laser irradiation.

In the applying of a pressure and irradiating of a laser, the pressure may be 0.4 MPa or more, and the laser may be an area laser having an output power of 100 W or more and may be applied for 5 seconds or less.

For example, the bonded structure 2000 may be irradiated for 1 to 5 seconds with an area laser having an output power of 100 W to 200 W while being pressed at a pressure of 0.4 MPa to 0.8 MPa.

Within the above ranges, when the bonded structure 2000 is pressed and simultaneously heated by using an area laser to raise the temperature of a wide range of the bonded structure 2000, the curable matrix 100 included in the bonded structure 2000 may exhibit reducing properties, and the oxide films 210 on the surfaces of the conductive particles 200 included in the conductive bonding layer may be removed, thereby enhancing the wettability of the conductive particles 200 and achieving the effects of the present invention.

The output power may be controlled within the above ranges to prevent damage to the first electronic component 1, and, for example, it is preferable that the output be determined within a range of temperatures capable of preventing damage to the first electronic component 1 and the second electronic component 5.

In one embodiment, the laser in operation S20 may raise the temperature of the bonded structure 2000 at a rate of 200° C./sec or less. For example, the bonded structure 2000 may be rapidly heated at a rate in a range of 1 to 120° C./sec to apply instantaneous thermal shock to the conductive particles 200, thereby more effectively removing the oxide films 210 on the surfaces of the conductive particles 200.

In operation S20, the bonded structure 2000 forms the conductive bonding layer, and the conductive bonding layer may electrically connect between metal pads of the substrate 1 and the electronic device 5 and form a conductive path 220 with the metal pads.

After operation S20, a degree of cure of a thermosetting resin included in the curable matrix 100 may be 0.1 or less.

In this case, the degree of cure of the thermosetting resin may be determined by measuring and comparing total heat generation in a differential scanning calorimetry (DSC) heating experiment between a material that has not undergone the laser application process and a material that has undergone the laser application process.

Referring to FIG. 6, when the laser irradiation is stopped and the pressure is released, a thickness d1 of the conductive bonding layer may be restored due to elasticity of the polymer spacers 300.

Since the laser irradiation and the pressing are performed for a short period of time over the entire area of the bonded structure 2000, only a portion of the thermosetting resin may be cured within the above range while the remainder may remain uncured, and an additional curing process is required to complete the bonding of the substrate 1 and the electronic device 5.

The bonded structure 2000 is cured (S30).

In operation S20, the conductive bonding layer is formed in the bonded structure 2000 by laser irradiation and pressing, and in operation S30, the bonded structure 2000 is cured to complete the bonding.

The curing may be performed at a temperature capable of curing the thermosetting resin, and, for example, a degree of cure of 0.7 or more may be achieved by curing the bonded structure 2000 at 100 to 140° C. for 1 to 3 hours.

In operation S30, the bonded structure 2000 is cured so that the conductive path 220 is formed between a first metal pad of the substrate and a second metal pad of the electronic device, and the bonding strength of the conductive bonding layer is increased, thereby enabling the substrate and the electronic device to be bonded very effectively.

Accordingly, in the method of manufacturing a bonded structure according to still another aspect of the present invention, a high-temperature and high-pressure bonding process is not required, and, the entire bonding surface is instantaneously irradiated with an area laser at room temperature and pressed, thereby applying thermal shock to the conductive bonding layer, enhancing the wettability of the conductive particles 200, forming a conductive path between the metal pads, and significantly increasing the efficiency of the pressing process.

Yet another aspect of the present invention relates to a method of manufacturing a bonded structure using the anisotropic conductive bonding material including a gallium-based alloy.

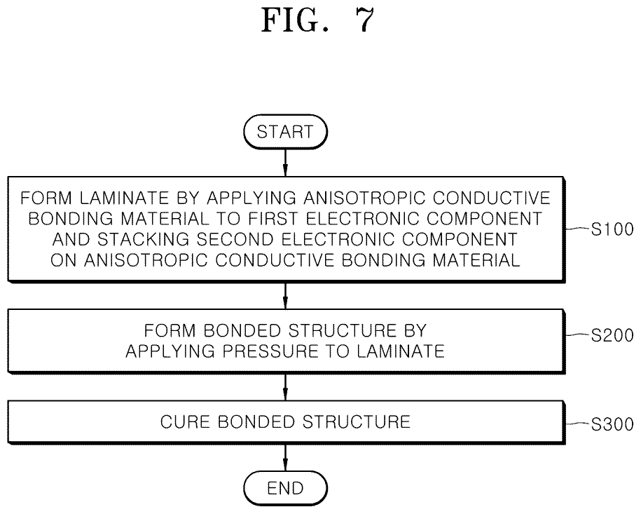

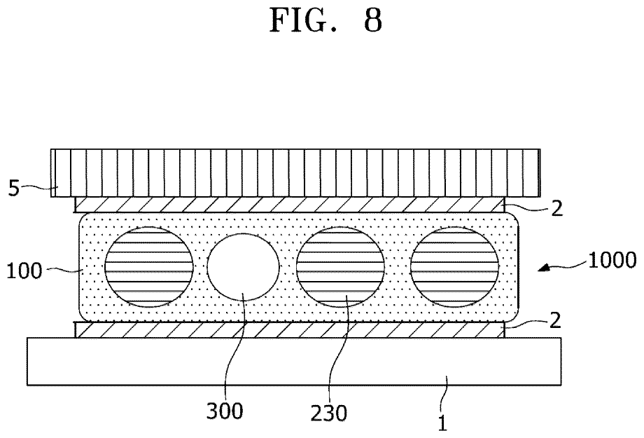

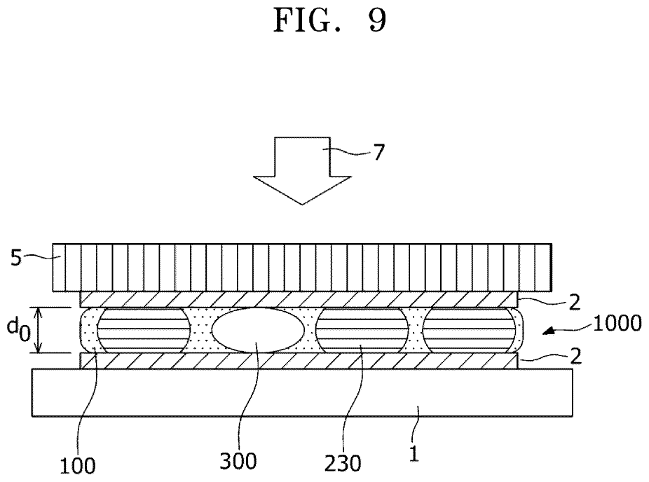

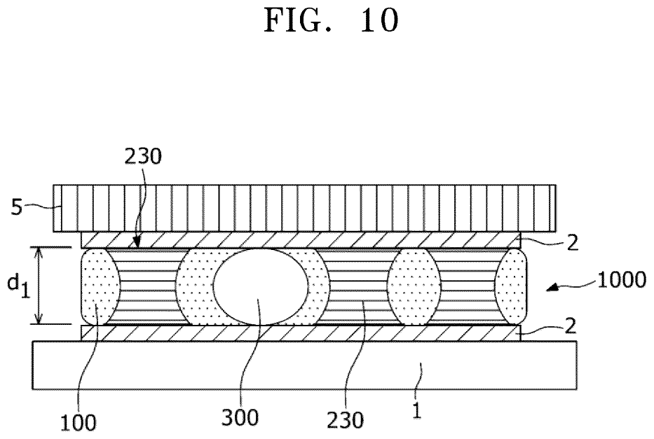

FIG. 7 is a process flowchart of the method of manufacturing a bonded structure using the anisotropic conductive bonding material according to yet another aspect of the present invention, FIG. 8 is a schematic view illustrating a bonded structure in which the anisotropic conductive bonding material including conductive particles containing a gallium-based alloy is disposed between a substrate and an electronic device in the method of manufacturing a bonded structure using the anisotropic conductive bonding material according to another embodiment of the present invention, FIG. 9 is a schematic view illustrating a pressing process applied to the bonded structure including conductive particles containing a gallium-based alloy in the method of manufacturing a bonded structure using the anisotropic conductive bonding material according to another embodiment of the present invention, and FIG. 10 is a schematic view illustrating a state in which a base resin is cured after the pressing process of the bonded structure including conductive particles containing a gallium-based alloy in the method of manufacturing a bonded structure using the anisotropic conductive bonding material according to another embodiment of the present invention.

Referring to FIGS. 7 to 10, the method of manufacturing a bonded structure includes applying the anisotropic conductive bonding material to a first electronic component 1 and stacking a second electronic component 5 on the anisotropic conductive bonding material to form a laminate, applying a pressure to the laminate to form a bonded structure, and curing the bonded structure.

First, the anisotropic conductive bonding material may be prepared by introducing a conductive particle agglomeration into a thermosetting resin to prepare a mixed composition, pulverizing the conductive particle agglomeration in the mixed composition by applying ultrasonic waves, and thereafter mixing a curable matrix and polymer spacers into the mixed composition.

For example, a mixed solution may be prepared by mixing a gallium-based alloy including gallium and at least one metal selected from gallium or indium (In), dysprosium (Dy), tin (Sn), and zinc (Zn), with a curable matrix 100 and polymer spacers 300, and the anisotropic conductive bonding material may be prepared by ultrasonically treating the mixed solution.

Specifically, the anisotropic conductive bonding material may be prepared by preparing a mixed solution by mixing the gallium or gallium-based alloy with the curable matrix 100 and the polymer spacers 300 so that the gallium or gallium-based alloy is dispersed in the curable matrix 100, and then ultrasonically treating the mixed solution.

The ultrasonic treatment may prevent an oxide film 210 from being formed on surfaces of the gallium or gallium-based alloy.

For example, when the gallium or gallium-based alloy is dispersed in the curable matrix 100 and subjected to ultrasonic treatment at a temperature of 50° C. or lower, conductive particles 200 having an average diameter of 1 μm to 100 μm may be formed in the curable matrix 100, and the conductive particles 200 may be uniformly dispersed in the curable matrix 100. Since the conductive particles 200 are formed inside the curable matrix 100 that exhibits reducing properties capable of removing the oxide films 210, the oxide films 210 are not formed on the surfaces of the conductive particles 200.

Subsequently, the anisotropic conductive bonding material that has been prepared is applied to the first electronic component 1, and the second electronic component 5 is stacked on the anisotropic conductive bonding material 1000 to form a laminate (S100).

Referring to FIG. 8, the conductive particles 200 may be dispersed in the anisotropic conductive bonding material 1000, which is in an uncured solution state at room temperature, so that a laminate may be very easily formed between the substrate 1 and the electronic device 5.

Pressure is applied to the laminate to form a bonded structure 2000 (S200).

Referring to FIG. 9, one surface of the bonded structure 2000 may be pressed to compress the conductive bonding layer 1000 in the bonded structure 2000, and polymer spacers may be included in the conductive bonding layer 1000 and compressed together, so that the conductive bonding layer may be compressed to a predetermined thickness do.

In the pressing operation, the bonded structure 2000 may be pressed at a pressure of 0.4 MPa or more.

The pressing may be performed at a pressure of 0.4 MPa or more, and, for example, may be performed at a pressure of 0.4 MPa to 0.8 MPa.

By pressing within the above range, the conductive particles 200 may come into contact with a first metal pad 2 and a second metal pad 2 of a substrate and an electronic device, and since the conductive particles 200 do not have the oxide films 210 on their surfaces, the wettability of the conductive particles 200 may be enhanced merely by pressing, thereby forming a conductive path 230.

In one embodiment, the first metal pad 2 or the second metal pad 2 may include Au.

When the first metal pad 2 or the second metal pad 2 is a metal pad including Au, the wettability of the conductive bonding layer may be enhanced merely by pressing at room temperature, and an intermetallic compound of AuGaz may be formed at room temperature, thereby forming a very stable electrical connection.

The bonded structure 2000 is cured (S300).

Even after the conductive path is formed in the conductive bonding layer of the bonded structure 2000, the curable matrix 100 remains in a liquid state with a degree of cure of 0.1 or less, and additional curing is required. For example, the bonded structure 2000 may be cured at 100° C. to 140° C. for 1 to 3 hours.

Through this curing, the conductive bonding layer 1000 between the first electronic component 1 and the second electronic component 5 is cured, thereby manufacturing the bonded structure.

Accordingly, in the method of manufacturing a bonded structure according to yet another aspect of the present invention, the substrate and the electronic device may be bonded using the anisotropic conductive bonding material 1000, and a high-temperature and high-pressure bonding process is not required, thereby preventing thermal damage to the substrate or the electronic device. Furthermore, energy used during bonding may be significantly reduced, thereby improving manufacturing efficiency.

When gallium or a gallium-based alloy is used as the conductive particles and is directly dispersed in the curable matrix 100 having reducing properties, the oxide films 210 on the surfaces of the particles are removed within the curable matrix 100, so that no separate removal process of the oxide films 210 is required and manufacturing efficiency may be further improved. In addition, since the conductive particles 200 including gallium or a gallium-based alloy exist in a liquid state at room temperature or higher, the wettability of the conductive particles 200 may be enhanced merely by pressing at room temperature, thereby forming the conductive path 230 between the metal pads and enabling bonding.

Hereinafter, preferred examples are presented to aid in understanding of the present invention. However, the following examples are merely illustrative and are not intended to limit the scope of the present invention.

### Example 1

An anisotropic conductive bonding material was prepared according to the composition shown in Table 1 below.

TABLE 1

| Composition | Component | Content | |
|---|---|---|---|
| Curable matrix | Bisphenol-F diglycidyl ether | 66 | wt % |
| | (DGEBF) (epoxy) | | |
| Curing agent | Amine | 4 | wt % |
| Reducing agent | Acetic acid | 16 | wt % |

| | | |
|---|---|---|
| Conductive particles | Gallium | (Average diameter |
| | | 15 μm) 12 wt % |
| Polymer spacers | PMMA | (Average diameter |
| | | 5 μm) 2 wt % |

### Example 2

A polyimide (PI) substrate and a silicon device were bonded using the anisotropic conductive bonding material prepared in Example 1.

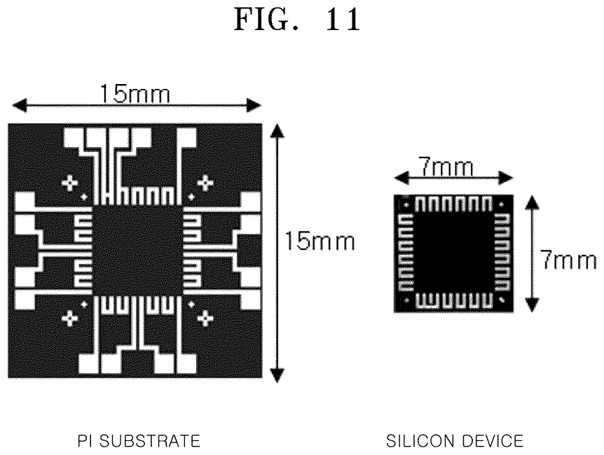

FIG. 11 is a schematic view illustrating an example of the substrate and the electronic device in the room-temperature pressure bonding method according to one embodiment of the present invention.

Referring to FIG. 11, a silicon device having a size of 7 mm×7 mm and a thickness of 100 μm and a PI substrate having a size of 15 mm×15 mm and a thickness of 70 μm were fabricated. Each of copper (Cu) metal pads provided on the silicon device and the PI substrate had a length of 400 μm and a width of 200 μm, and a pitch between adjacent metal lines was 400 μm.

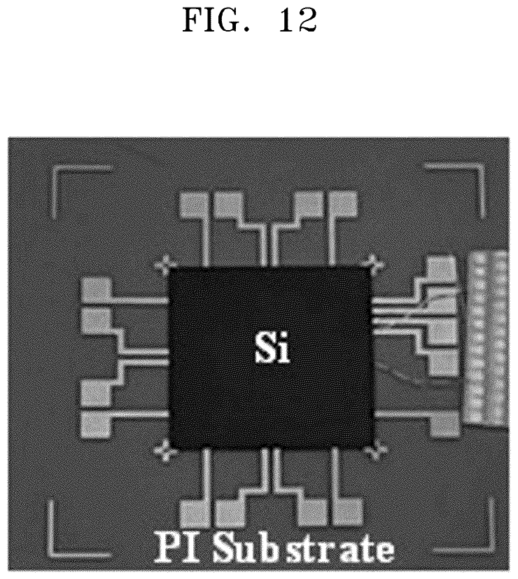

FIG. 12 illustrates a state in which the anisotropic conductive bonding material is applied onto the PI substrate and covered with the silicon device in the room-temperature pressure bonding method according to one embodiment of the present invention.

After the anisotropic conductive bonding material according to Example 1 was applied onto the Cu metal pads of the PI substrate, a bonding process was performed as shown in FIG. 5 by adjusting an output power of an area laser at a sample stage temperature of 25° C., irradiating the area laser for 5 seconds, and applying a pressure of 0.4 MPa.

A post-curing process was then performed at 120° C. for 2 hours to complete the bonding process.

### Experimental Example 1

To confirm whether conductive particles can be produced using liquid gallium powder, a melting point of the gallium powder was measured using DSC. After impregnating the gallium powder in a solvent having relatively low viscosity and applying ultrasonic waves to the mixture, formation of conductive particles and sizes of the conductive particles were confirmed.

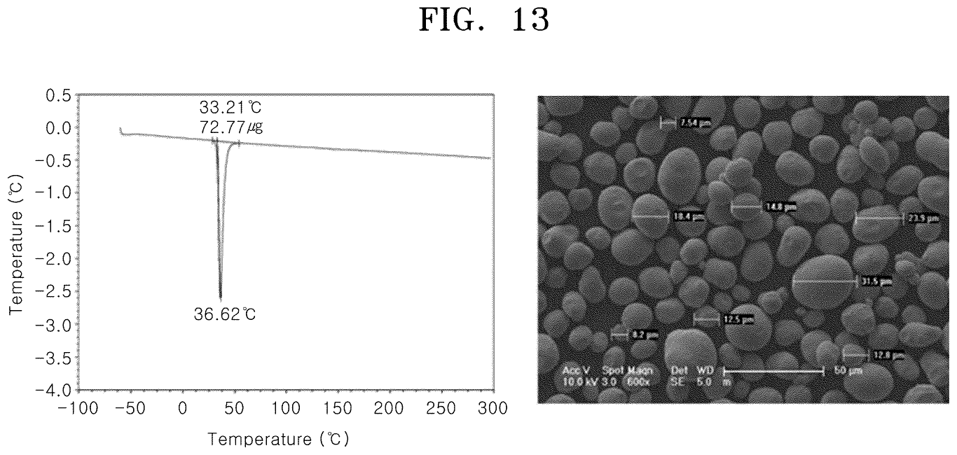

FIG. 13 illustrates the result of a DSC analysis and a scanning electron microscope (SEM) image of the conductive particles including gallium in the anisotropic conductive bonding material according to one embodiment of the present invention.

Referring to FIG. 13, the melting point of the gallium powder was measured to be 37° C. according to the result of DSC analysis, and it was confirmed that conductive particles having an average diameter of 15 μm can be produced by ultrasonically treating the gallium powder at room temperature.

### Experimental Example 2

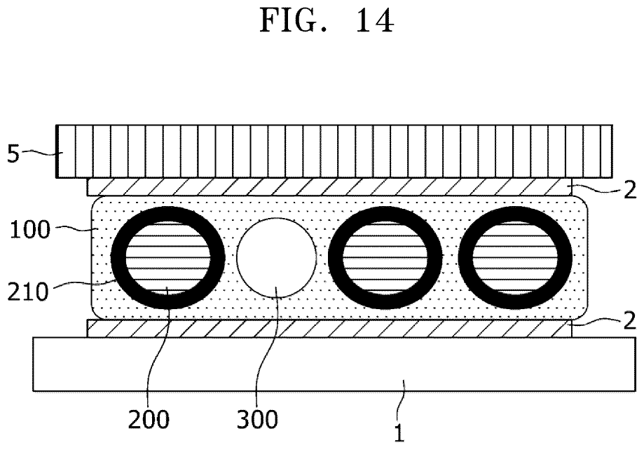

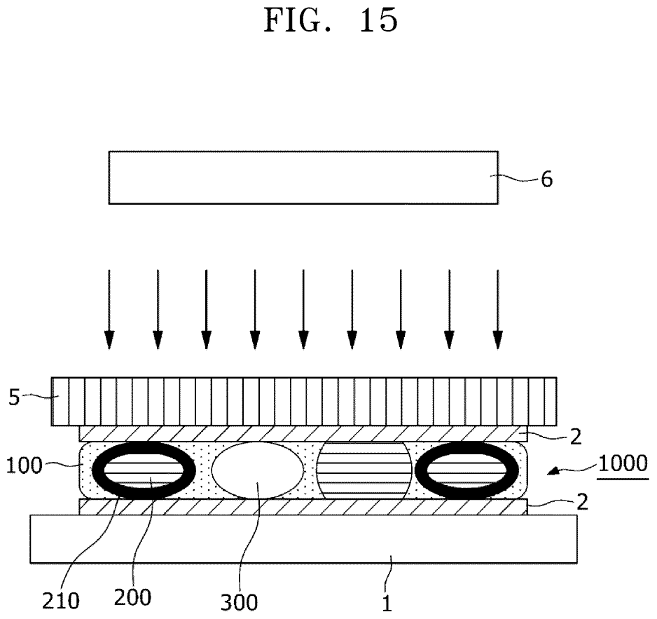

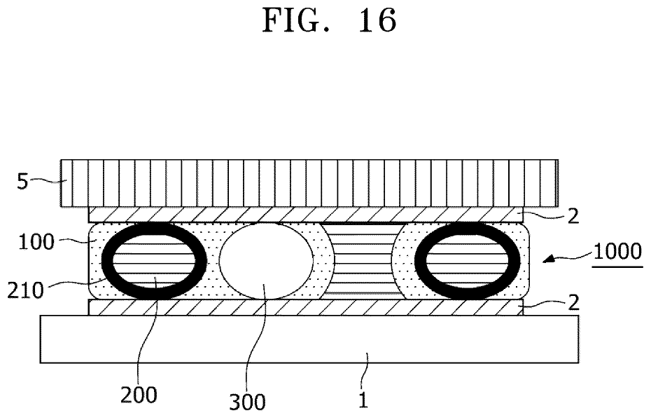

FIG. 14 is a schematic view illustrating a bonded structure in which an anisotropic conductive bonding material including conductive particles whose surface oxide films have not been removed is disposed, and FIG. 15 is a schematic view illustrating a state in which the surface oxide films of the conductive particles are removed when a low-power area laser is radiated onto and a low pressure is applied to the bonded structure in which the anisotropic conductive bonding material including conductive particles whose surface oxide films have not been removed is disposed. FIG. 16 is a schematic view illustrating the bonded structure in a state in which a conductive path is formed as the surface oxide films of some conductive particles are removed.

Referring to FIGS. 14 to 16, when the anisotropic conductive bonding material according to Example 1 was applied to the substrate to prepare a bonded structure, and a low pressure was applied while the output power of the area laser did not reach a certain level, only some of the conductive particles had their surface oxide films removed even though the curable matrix exhibited reducing properties. The conductive particles from which the oxide films were not removed were in physical contact with the metal pads but did not form a complete electrical connection, and thus a high resistance was measured between the substrates. Accordingly, it was confirmed that area-laser output and applied pressure above certain thresholds are required.

### Experimental Example 3

In Example 2, bonding was performed by adjusting the output power of the area laser to 85 W, 105 W, and 200 W, and 4-point probe resistance was measured after the bonding and post-curing processes.

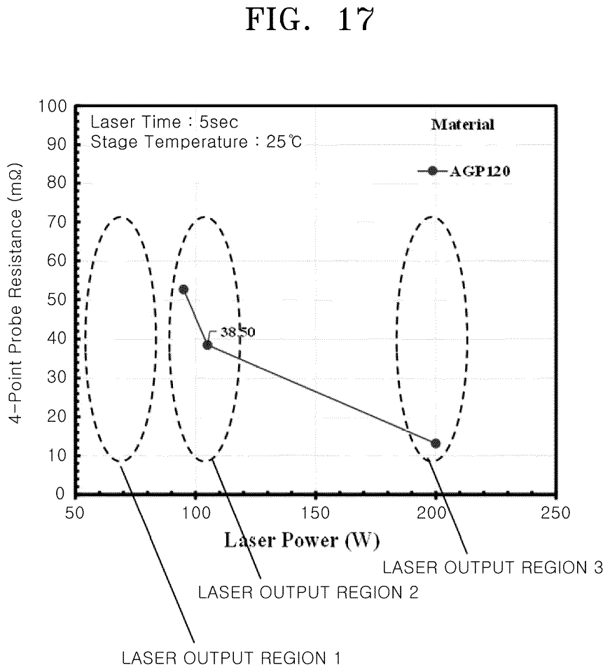

FIG. 17 is a graph showing results of measuring 4-point probe resistance between the bonded substrate and electronic device while varying the output power of the area laser in the room-temperature pressure bonding according to one embodiment of the present invention.

Referring to FIG. 17, when the output power of the area laser was lower than 85 W under an applied pressure of 0.4 MPa, the resistance was measured as infinite. As confirmed in Experimental Example 2, it was confirmed that unless laser irradiation and pressure above certain thresholds are simultaneously applied, the wettability of the conductive particles cannot be fully realized even in the curable matrix exhibiting reducing properties.

Meanwhile, under the same pressure conditions, when the output power of the area laser was 105 W and 200 W, the resistances were measured to be 38.5Ω and 13.15Ω, respectively, and it was confirmed that, under the same mechanical impact conditions, the oxide film on the surface of the gallium powder can be effectively removed as the intensity of thermal shock increases. In conclusion, it was confirmed that, in the gallium-based anisotropic conductive bonding material, the degree of oxide-film removal from the gallium powder can be effectively controlled by the magnitude of the applied pressure and the output power of the area laser that generates thermal shock. In addition, the curable matrix exhibiting reducing properties confirmed to be highly effective in removing oxide films from both the metal pads and the surfaces of the gallium powder.

An anisotropic conductive bonding material according to the present invention includes liquid gallium metal as conductive particles and exhibits wettability upon laser irradiation and compression, thereby eliminating the need for a high-temperature and high-pressure thermosetting process and effectively preventing thermal damage to substrates and electronic devices during fabrication of a bonded structure.

Further, a room-temperature pressure bonding method using an anisotropic conductive bonding material can allow liquid gallium, which forms a strong oxide film at room temperature, to form an electrical conduction path between metals by removing the oxide film through adjustment of the intensity of a laser and an applied mechanical pressure, thereby achieving a more robust bonded state. A metal-to-metal bonded region can exhibit anisotropic conductivity, and because the liquid gallium present at room temperature or higher remains in a liquid state and significantly reduces stress in the bonded region, cracks do not occur in the bonded region even under external impact, and a short circuit caused by cracking can be prevented.

The present invention has been described above with reference to exemplary embodiments. Those skilled in the art related to the present invention will readily appreciate that many modifications are possible without departing from the essential features of the above description. Therefore, the disclosed embodiments are to be considered in an illustrative sense rather than a restrictive sense. The scope of the present invention is indicated in the claims rather than the above-described description, and all differences within the scope equivalent thereto should be construed as falling within the present invention.

What is claimed is:

1. An anisotropic conductive bonding material comprising:
a curable matrix;
conductive particles; and
polymer spacers,
wherein the conductive particles include gallium (Ga) or a gallium-based alloy,
wherein the gallium-based alloy includes gallium and one or more metals selected from indium (In), dysprosium (Dy), tin (Sn), and zinc (Zn).

2. The anisotropic conductive bonding material of claim 1, wherein the conductive particles have an average diameter of 1 μm to 100 μm.

3. The anisotropic conductive bonding material of claim 1, wherein the curable matrix includes a thermosetting resin, a curing agent, a reducing agent, and a catalyst.

4. The anisotropic conductive bonding material of claim 3, wherein the reducing agent includes one or more selected from formic acid, acetic acid, lactic acid, glutamic acid, oleic acid, rosolic acid, 2,2-bis(hydroxymethylene) propanoic acid, butanoic acid, propanoic acid, tannic acid, gluconic acid, pentanoic acid, hexanoic acid, hydrobromic acid, hydrochloric acid, uric acid, hydrofluoric acid, sulfuric acid, benzylglutaric acid, malic acid, phosphoric acid, oxalic acid, uranic acid, hydrochloride, perchloric acid, gallic acid, phosphorous acid, citric acid, malonic acid, tartaric acid, phthalic acid, cinnamic acid, glutaric acid, propionic acid, stearic acid, ascorbic acid, acetylsalicylic acid, azelaic acid, benzylic acid, and fumaric acid.

5. The anisotropic conductive bonding material of claim 1, wherein the anisotropic conductive bonding material includes 10 to 30 parts by weight of the conductive particles and 1 to 5 parts by weight of the polymer spacers based on 100 parts by weight of the curable matrix.

6. A bonded structure comprising:
a first electronic component;
a second electronic component facing the first electronic component; and
a conductive bonding layer interposed between the first electronic component and the second electronic component and electrically connecting the first electronic component and the second electronic component,
wherein the conductive bonding layer includes the anisotropic conductive bonding material of claim 1.

7. The bonded structure of claim 6, wherein the first electronic component or the second electronic component includes a printed circuit board.

8. The bonded structure of claim 6, wherein the polymer spacers included in the conductive bonding layer maintain a spacing between the first electronic component and the second electronic component.

9. The bonded structure of claim 6, wherein the first electronic component includes a substrate and a first metal pad formed on an upper portion of the substrate and in contact with the conductive bonding layer, and
the second electronic component includes an electronic device and a second metal pad formed on a lower portion of the electronic device and in contact with the conductive bonding layer.

10. A method of manufacturing a bonded structure, comprising:
forming a laminate by applying the anisotropic conductive bonding material of claim 1 to a first electronic component and stacking a second electronic component on the anisotropic conductive bonding material;
forming a bonded structure by applying a pressure to the laminate and irradiating the laminate with a laser; and
curing the bonded structure.

11. The method of claim 10, wherein the anisotropic conductive bonding material is prepared by pulverizing a conductive particle agglomeration and mixing the pulverized conductive particles with the curable matrix and the polymer spacers.

12. The method of claim 10, wherein the pressure is greater than or equal to 0.4 MPa, and the laser has an output power greater than or equal to 100 W.

13. The method of claim 10, wherein the laser increases a temperature of the bonded structure at a rate of 200° C./sec or less.

14. The method of claim 11, wherein oxide films are present on surfaces of the pulverized conductive particles, and
the oxide films are removed by the pressure and the laser.

15. The method of claim 11, wherein the pulverized conductive particles are prepared by preparing a mixture by introducing the conductive particle agglomeration into a solvent, pulverizing the conductive particle agglomeration by applying ultrasonic waves to the mixture, and drying the mixture to remove the solvent.
